(19) United States
(12) Patent Application Publication
(10) Pub. No.: US 2003/0015797 A1
(43) Pub. Date: Jan. 23, 2003

(54) Semiconductor device

(76) Inventor: Takeshi Nogawa, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/175,445

(22) Filed: Jun. 20, 2002

(30) Foreign Application Priority Data
Jul. 23, 2001 (JP) 2001-222090

(51) Int. Cl. H01L 23/48; H01L 23/52; H01L 29/40

(52) U.S. Cl. 257/758

(57) ABSTRACT

The transistors share the sameness in the areas of gate oxide films 2a and 2b, and in those of the side surfaces of sixth metal wiring layers 15a and 15b to be exposed in a metallization patterning process by a plasma process such as plasma etching and the like in order to form the uppermost layer. For this reason, the transistors share the sameness in antenna ratio. The pairing transistors are suffered from the damage of the same level induced by plasma transmitted from the side surfaces of sixth metal wiring layers 15a and 15b to gate oxide films 2a and 2b.

### BACKGROUND OF THE INVENTION

1. Field of the Invention

The present invention relates to a semiconductor device used for a large-scale integrated circuit (LSI).

2. Description of Related Art

A semiconductor device such as an LSI includes a variety of transistors thereon in compliance with the application. These transistors are formed by use of a well-known thin film technology such as plasma CVD and plasma etching for instance.

A conventional semiconductor device is manufactured through many processes as shown in FIGS. 5A, 5B and FIGS. 6A, 6B, for instance. FIG. 5A is a sectional view showing a metallization patterning process in a method of manufacturing the conventional semiconductor device. FIG. 5B is a plan view showing the enlarged principle part of FIG. 5A. FIG. 6A is a sectional view showing an interlayer film forming process over the metal wiring in a method of manufacturing the conventional semiconductor device. FIG. 6B is a plan view showing the enlarged principle part of FIG. 6A.

Referring to the FIG. 5A, semiconductor substrate 1 is formed of silicon or the like. Thin gate oxide films 2a and 2b consisting of silicon oxide for instance are formed in the predetermined positions on semiconductor substrate 1, and gate electrodes 3a and 3b are formed on gate oxide films 2a and 2b. Gate electrodes 3a and 3b are arranged to act as the gates of two transistors as shown in FIGS. 5 A and 5B. Here, other components such as an emitter and a collector are not shown in the conventional device. First interlayer film 4 is deposited and formed over gate electrodes 3a and 3b, and semiconductor substrate 1 by means of plasma CVD technology or the like. Through-holes 5a and 5b extending to gate electrodes 3a and 3b, respectively, are formed through first interlayer film 4 by means of etching technology or the like, and first metal wiring layers 6a and 6b consisting of a metal such as aluminum for instance are formed within through-holes 5a and 5b, respectively, by means of sputtering technology or the like. Second metal wiring layers 7a and 7b consisting of a metal such as aluminum for instance are formed over first metal wiring layers 6a and 6b, and second interlayer film 8 is deposited and formed over second metal wiring layers 7a, 7b, and first interlayer film 4 by means of plasma CVD technology or the like. Through-holes 9a and 9b extending to second metal wiring layers 7a and 7b, respectively, are formed through second interlayer film 8 by etching technology or the like, and third metal wiring layers 10a and 10b consisting of a metal such as aluminum for instance are formed within through-holes 9a and 9b, respectively, by means of sputtering technology or the like. Fourth metal wiring layers 11a and 11b consisting of a metal such as aluminum for instance are formed over third metal wiring layers 10a and 10b, and third interlayer film 12 is deposited and formed over fourth metal wiring layers 11a, 11b, and second interlayer film 8 by means of plasma CVD technology or the like. Through-holes 13a and 13b extending to fourth metal wiring layers 11a and 11b, respectively, are formed through third interlayer film 12 by means of etching technology, and fifth metal wiring layers 14a and 14b consisting of a metal such as aluminum for instance are formed within through-holes 13a and 13b, respectively, by means of sputtering technology or the like. Sixth metal wiring layers 15a and 15b consisting of a metal such as aluminum for instance are formed over fifth metal wiring layers 14a and 14b.

Sixth metal wiring layers 15a and 15b are formed in the following processes for instance. First of all, as shown in FIG. 5A, metal layer A consisting of a metal such as aluminum for instance is formed over third interlayer film 12, and then resists 16a and 16b consisting of photocurable resin for instance are formed thereon. After that, parts in metal layer A that is not covered with resists 16a and 16b are removed by means of dry etching executed in plasma such as plasma etching and reactive ion etching or the like, to thereby form sixth metal wiring layers 15a and 15b (The metallization patterning process). At this time, because the side surfaces of sixth metal wiring layers 15a and 15b are not covered with resists 16a and 16b, gate oxide films 2a and 2b are suffered from the damage induced by plasma, which is transmitted through the side surfaces thereof and through sixth metal wiring layers 15a and 15b, fifth metal wiring layers 14a and 14b, fourth metal wiring layers 11a and 11b, third metal wiring layers 10a and 10b, second metal wiring layers 7a and 7b, first metal wiring layers 6a and 6b, and gate electrode 3a and 3b. When the damage induced by plasma is thus caused, a local electric field is generated within semiconductor substrate 1, and thereby a tunnel current flows between gate oxide films 2a and 2b. This situation is equivalent to one where the semiconductor device is exposed to a severe reliability test condition.

In the conventional device, the discussion is concentrated upon the damage induced by plasma that is caused to gate oxide films 2a and 2b in the plasma process, which is directly transmitted to the side surfaces of sixth metal wiring layers 15a and 15b. However, gate oxide films 2a and 2b are also suffered from the damage induced by plasma in the plasma processes, which is directly transmitted to the side surfaces of fourth metal wiring layers 11a and 11b, and second metal wiring layers 7a and 7b.

Moreover, even in the interlayer film forming process following the metallization patterning process as a post-process, gate oxide films 2a and 2b are also suffered from the damage induced by plasma. That is, after resists 16a and 16b shown in FIGS. 5A and 5B are removed from the surfaces of sixth metal wiring layers 15a and 15b, oxide film B as the fourth interlayer film is formed over sixth metal wiring layers 15a, 15b, and third interlayer film 12 by means of plasma CVD technology or the like (The interlayer film forming process). At this time, since the whole surfaces of sixth metal wiring layers 15a and 15b are subjected to the plasma, gate oxide films 2a and 2b are also suffered from the damage induced by plasma in this process. As a result, since the damage that is caused to gate oxide films 2a and 2b in each process is accumulated therein, the characteristics of a transistor having gate oxide films 2a and 2b will be inferior to the predetermined ones.

In the conventional device, the discussion is concentrated upon the damage induced by plasma that is caused to gate oxide films 2a and 2b in the interlayer film forming process by means of the plasma CVD, which is directly transmitted to the whole surfaces of sixth metal wiring layers 15a and 15b. However, gate oxide films 2a and 2b are also suffered from the damage induced by plasma in the interlayer film forming process by means of the plasma CVD, which is directly transmitted to the whole surfaces of fourth metal wiring layers 11a and 11b, and second metal wiring layers 7a and 7b.

In recent transistors, long wirings have been often used to connect with small gate electrodes 3a and 3b. As a result, a tunnel current flowing through a unit area increases, and the workpiece is exposed to an increased severe stress in the manufacturing process. Therefore, upon manufacturing a transistor, the area ratio (hereinafter referred to as antenna ratio) of gate electrodes 3a and 3b to each metal wiring to be connected therewith are considered as an important parameter for evaluating the damage induced by plasma that is caused to gate oxide films 2a and 2b in each manufacturing process. Many efforts have been made to reduce the damage induced by plasma by use of the antenna ratio as a reference index.

In the method of manufacturing the conventional semiconductor device, the antenna ratio is determined individually for each transistor to set the characteristics of the transistor. However, upon manufacturing a semiconductor device including a plurality of transistors having the same characteristics formed on the same semiconductor substrate, the damage induced by plasma cannot be rendered uniform among the transistors. Therefore, a plurality of transistors formed on the same semiconductor substrate cannot have the same characteristics. As a result, there has been a problem that circuitry does not work well, for instance, output voltage varying among the transistors having the same characteristics.

That is, in the conventional semiconductor devices shown in FIGS. 5A, 5B and FIGS. 6A, 6B, since either of sixth metal wiring layers 15a located on the right sides in the figures are larger than sixth metal wiring layers 15b located on the left sides, there are differences in area between the right sides and the left sides in FIGS. 5A and 5B for instance, with respect to the side surfaces of sixth metal wiring layers 15a and 15b that are exposed without being coated by resists 16a and 16b. Similarly, in FIG. 6A and FIG. 6B, the same differences are made in area between the right and left transistors with respect to the whole surfaces of exposed sixth metal wiring layers 15a and 15b. Accordingly, even if a transistor having gate electrode 3a and a transistor having gate electrode 3b have been initially designed such that they have the same characteristics, because the levels of damage induced by plasma that is caused to gate oxide films 2a and 2b are different, they make a difference in the degradation characteristics. As a result, the transistors having the same characteristics could not be manufactured.

### SUMMARY OF THE INVENTION

The present invention has been made to solve the above-mentioned problem. An object of the present invention is to provide a semiconductor device including a plurality of transistors having the same characteristics formed on the same semiconductor substrate, and a method of manufacturing the semiconductor device.

A semiconductor device according to the invention includes a plurality of transistors having the same characteristics formed on the same semiconductor substrate, wherein the transistors share the sameness in antenna ratio between an area of a gate oxide film of each transistor and an area of a metal wiring electrically connected with a gate electrode formed on the gate oxide film.

The semiconductor device according to the invention, wherein the metal wiring is connected with another circuit formed on the same semiconductor substrate.

The semiconductor device according to the invention, wherein the transistors share the sameness in exposed area of the metal wiring to be subjected to the plasma process.

### BRIEF DESCRIPTION OF THE DRAWINGS

FIG. 1A is a sectional view showing a metallization patterning process in a method of manufacturing a semiconductor device according to a first embodiment of the invention.

FIG. 1B is a plan view showing an enlarged principle part of FIG. 1A.

FIG. 2A is a sectional view showing an interlayer film forming process over the metal wiring in a method of manufacturing a semiconductor device according to a second embodiment of the invention.

FIG. 2B is a plan view showing an enlarged principle part of FIG. 2A.

FIG. 3A is a sectional view showing a metallization patterning process in a method of manufacturing a semiconductor device according to a third embodiment of the invention.

FIG. 3B is a sectional view showing an interlayer film forming process over the metal wiring following the metallization patterning process as a post-process shown in FIG. 3A.

FIG. 4A is a sectional view showing a metallization patterning process in a method of manufacturing a semiconductor device according to a fourth embodiment of the invention.

FIG. 4B is a sectional view showing an interlayer film forming process over the metal wiring following the metallization patterning process as a post-process shown in FIG. 4A.

FIG. 5A is a sectional view showing a metallization patterning process in a method of manufacturing the conventional semiconductor device.

FIG. 5B is a plan view showing an enlarged principle part of FIG. 5A.

FIG. 6A is a sectional view showing an interlayer film forming process over the metal wiring in a method of manufacturing the conventional semiconductor device.

FIG. 6B is a plan view showing an enlarged principle part of FIG. 6A.

### DETAILED DESCRIPTION OF THE PREFERRED EMBODIMENTS

Preferred embodiments of the present invention will be described in detail with reference to the attached drawings.

### First Embodiment

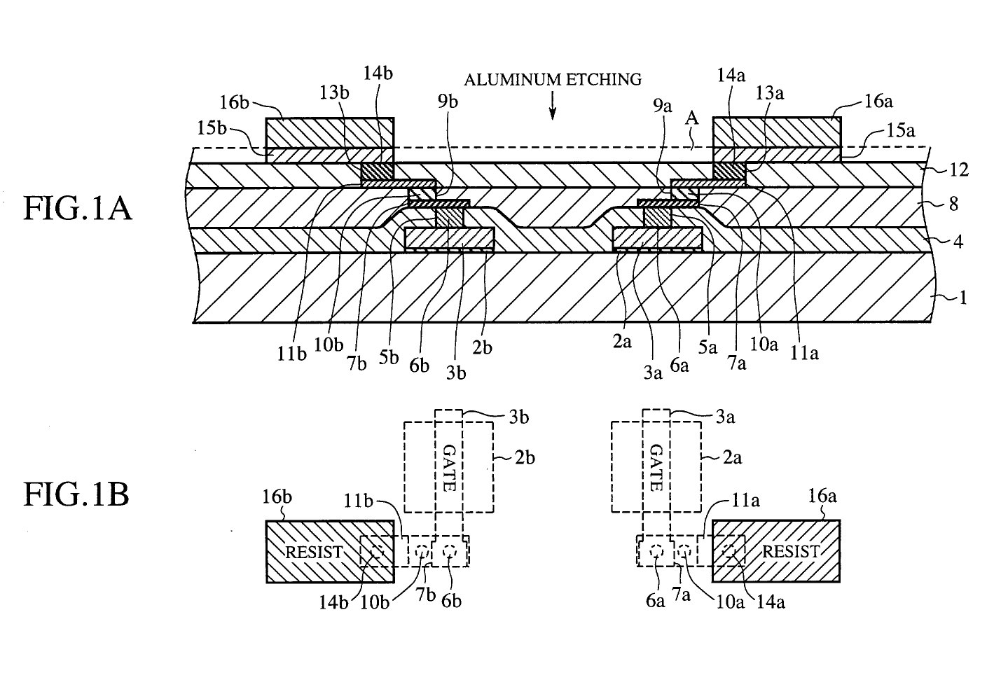

FIG. 1A is a sectional view showing a metallization pattering process in a method of manufacturing a semiconductor device according to the first embodiment of the invention. FIG. 1B is a plan view showing the enlarged principle part of FIG. 1A. In the first embodiment the same components as the conventional ones are designated by the same reference numerals, and thus the descriptions thereof are omitted.

The feature of the first embodiment is in that a plurality of transistors formed on the same semiconductor substrate share the sameness in antenna ratio between an area of a gate oxide film of each transistor and that of a side surface of a metal wiring layer (exposed area) to be exposed so as to directly exert an influence of plasma on the surface in a metallization patterning process by plasma process such as plasma etching and the like.

That is, in the first Embodiment as shown in FIGS. 1A and 1B, two transistors having the same characteristics (hereinafter referred to as “pairing transistors”) share the sameness in the areas of gate oxide films 2a and 2b, and in those of the side surfaces of sixth metal wiring layers 15a and 15b to be exposed in order to form the uppermost layer in the metallization patterning process by the plasma process such as plasma etching and the like. For this reason, the above-mentioned paring transistors share the sameness in antenna ratio, and in the plasma process, the paring transistors suffer from the damage of the same level induced by plasma that is caused to their gate oxide films 2a and 2b transmitted from the side surfaces of sixth metal wiring layers 15a and 15b. Consequently, the paring transistors have the same degradation characteristics, and therefore the pairing transistors formed on the same semiconductor substrate 1 can have the same characteristics.

As mentioned above, according to the first embodiment, since the paring transistors formed on the semiconductor substrate 1 share the sameness in antenna ratio between the areas of gate oxide films 2a and 2b and those of the side surfaces of sixth metal wiring layers 15a and 15b to be exposed in the metallization patterning process, the paring transistors suffer from the damage of the same level induced by plasma that is caused to gate oxide films 2a and 2b. As a result, the paring transistors can have the same characteristics.

While in the first embodiment the paring transistors share the sameness in the areas of gate oxide films 2a and 2b and in those of the side surfaces of sixth metal wiring layers 15a and 15b, if the pairing transistors share the sameness in antenna ratio, these areas may not necessarily be the same.

Further, while in the first embodiment in the plasma process directly applied to the side surfaces of sixth metal wiring layers 15a and 15b, the paring transistors suffer from the damage of the same level induced by plasma that is caused to gate oxide films 2a and 2b. Needless to say, in the plasma process directly applied to the side surfaces of fourth metal wiring layers 11a and 11b, and second metal wiring layers 7a and 7b, it is desirable for the paring transistors to suffer from the damage of the same level induced by plasma. However, if the pairing transistors are designed on the design philosophy such that they suffer from the damage of the same level in the whole processes of the method of manufacturing the semiconductor device, the damage induced by plasma in one plasma process may not necessarily be the same between the pairing transistors.

In addition, while in the first embodiment the pairing transistors formed on the same semiconductor substrate 1 have the same characteristics, there is imposed no limitation on the number of the transistors, only if the transistors are formed on semiconductor substrate 1 and have the same characteristics.

### Second Embodiment

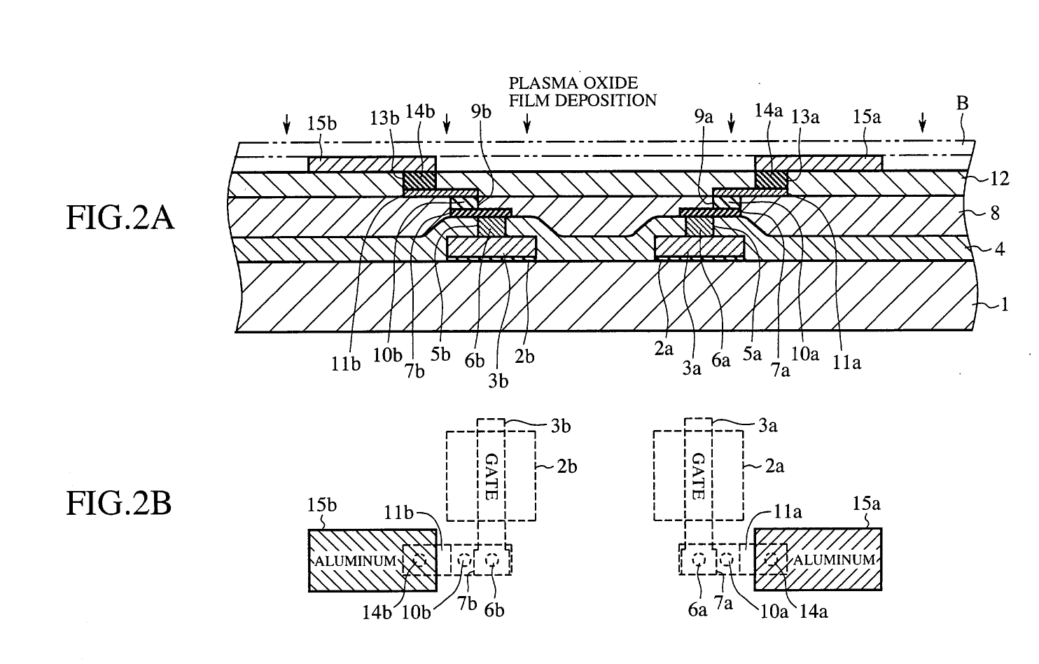

FIG. 2A is a sectional view showing an interlayer film forming process over the metal wiring in a method of manufacturing a semiconductor device according to the second embodiment of the invention. FIG. 2B is a plan view showing the enlarged principle part of FIG. 2A. In the second embodiment the same components as the ones in the first embodiment are designated by the same reference numerals, and thus the descriptions thereof are omitted.

The feature of the second embodiment is in that a plurality of transistors formed on the same semiconductor substrate share the sameness in antenna ratio between an area of a gate oxide film of each transistor and that of a surface of a metal wiring layer (exposed area) to be exposed so as to directly exert an influence of plasma on the surface in the interlayer film forming process by plasma process such as plasma CVD and the like.

That is, in the second embodiment as shown in FIGS. 2A and 2B, the paring transistors share the sameness in the areas of gate oxide films 2a and 2b, and in those of the whole surfaces (surface area) of sixth metal wiring layers 15a and 15b to be exposed in the interlayer film forming process by the plasma process such as plasma CVD and the like in order to form the uppermost layer. For this reason, the paring transistors share the sameness in antenna ratio, and in the plasma process, the paring transistors suffer from the damage of the same level induced by plasma that is caused to gate oxide films 2a and 2b transmitted from the whole surfaces of sixth metal wiring layers 15a and 15b. Consequently, the pairing transistors have the same degradation characteristics. As a result, the pairing transistors formed on the same semiconductor substrate 1 can have the same characteristics.

As mentioned above, according to the second embodiment, since the paring transistors formed on semiconductor substrate 1 share the sameness in antenna ratio between the areas of gate oxide films 2a and 2b of the transistors and the surface areas of sixth metal wiring layers 15a and 15b to be exposed in the interlayer film forming process, the paring transistors suffer from the damage of the same level induced by plasma that is caused to gate oxide films 2a and 2b. As a result, the pairing transistors can have the same characteristics.

In the second embodiment the paring transistors share the sameness in the areas of gate oxide films 2a and 2b and in the surface areas of sixth metal wiring layers 15a and 15b. However, if the paring transistors share the sameness in antenna ratio, these areas may not necessarily be the same.

Further, while in the second embodiment in the plasma process directly applied to the whole surfaces of sixth metal wiring layers 15a and 15b, the paring transistors suffer from the damage of the same level induced by plasma that is caused to gate oxide films 2a and 2b. Needless to say, in the plasma process directly applied to the whole surfaces of fourth metal wiring layers 11a and 11b, and second metal wiring layers 7a and 7b, it is preferable for the paring transistors to suffer from the damage of the same level induced by plasma. However, if the pairing transistors are designed on the design philosophy such that they suffer from the same damage of the same level in the whole processes of the method of manufacturing the semiconductor device, the damage induced by plasma in one plasma process may not necessarily be the same between the pairing transistors.

In addition, while in the second embodiment the pairing transistors formed in the same semiconductor substrate 1 have the same characteristics, there is imposed no limitation on the number of the transistors, only if the transistors are formed on semiconductor substrate 1 and have the same characteristics.

### Third Embodiment

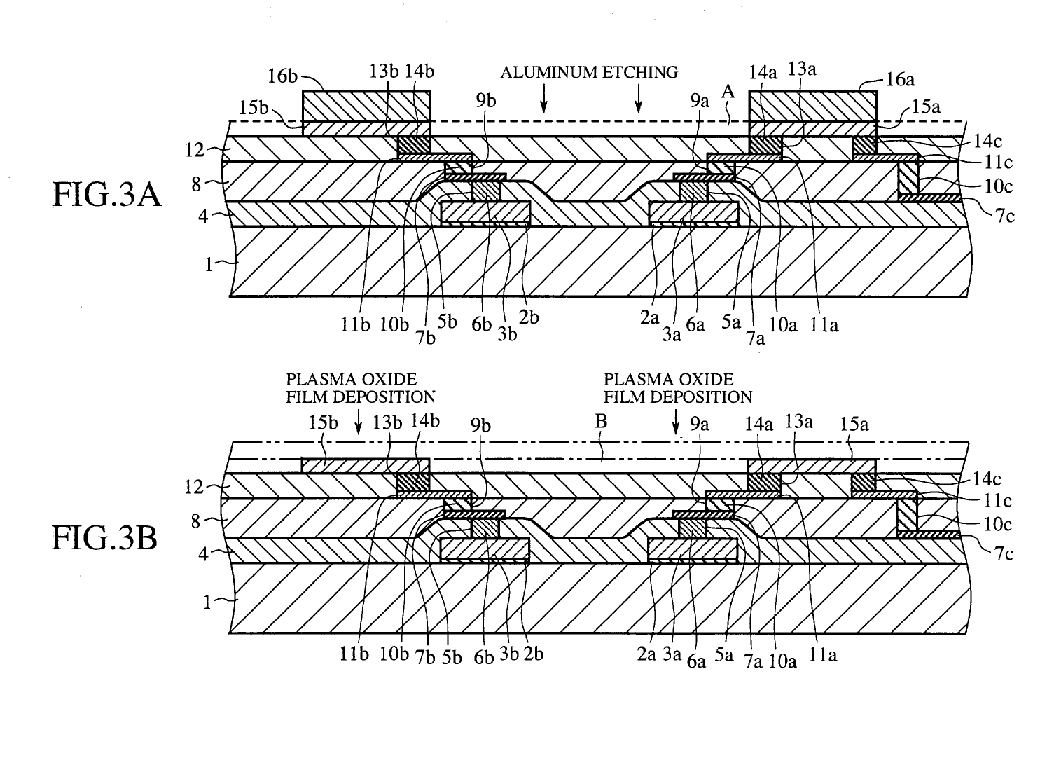

FIG. 3A is a sectional view showing a metallization patterning process in a method of manufacturing a semiconductor device according to the third embodiment of the invention. FIG. 3B is a sectional view showing an interlayer film forming process over the metal wiring following the metallization patterning process as a post-process shown in FIG. 3A. In the third embodiment the same components as the ones in the first embodiment are designated by the same reference numerals, and thus the descriptions thereof are omitted.

The feature of the third embodiment is in that sixth metal wiring 15a to be directly subjected to the plasma process both in the metallization patterning process of the first embodiment and in the interlayer film forming process of the second embodiment is connected with another circuit (not shown) formed on semiconductor substrate 1. That is, in the third embodiment as shown in FIGS. 3A and 3B, sixth metal wiring layer 15a is connected with another circuit (not shown) through fifth metal wiring layer 14c, fourth metal wiring layer 11c, third metal wiring layer 10c, and second metal wiring layer 7c. In this case, none of fifth metal wiring layer 14c, fourth metal wiring layer 11c, third metal wiring layer 10c, and second metal wiring layer 7c are connected with gate oxide film 2a before forming sixth metal wiring layer 15a. For this reason, the transistor including sixth metal wiring layer 15a does not suffer from the damage induced by plasma transmitted from other circuits (not shown).

As mentioned above, according to the third embodiment, the following effect is obtained besides that by the first embodiment or the second embodiment. That is, according to third embodiment, even if sixth metal wiring layer 15a to be directly subjected to the plasma process is connected with other circuits (not shown) formed on semiconductor substrate 1, gate oxide film 2a does not suffer from the damage induced by plasma transmitted from other circuits (not shown), but suffers only from the damage induced by plasma within each transistor. For this reason, freedom in the design of the metal wiring can be maintained.

### Fourth Embodiment

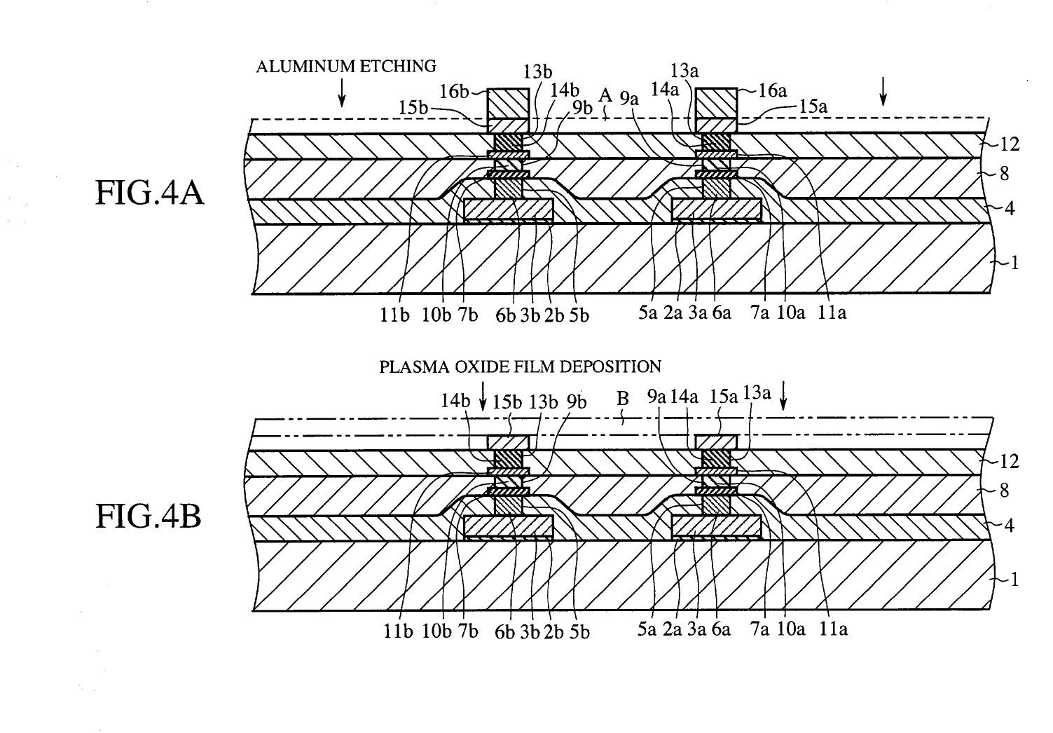

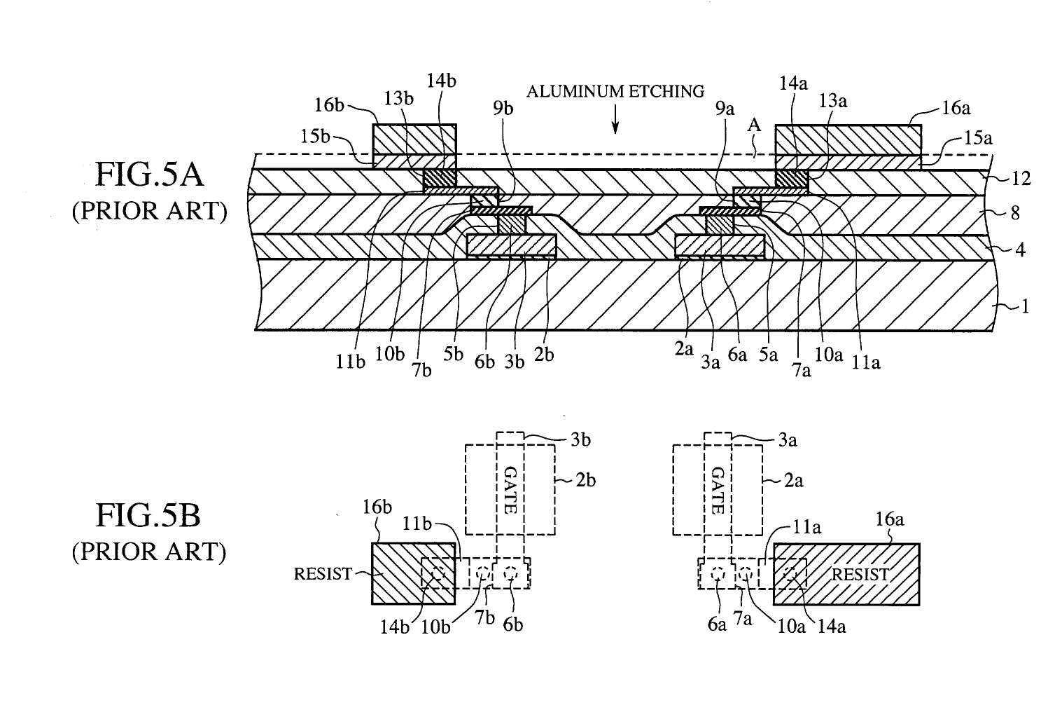

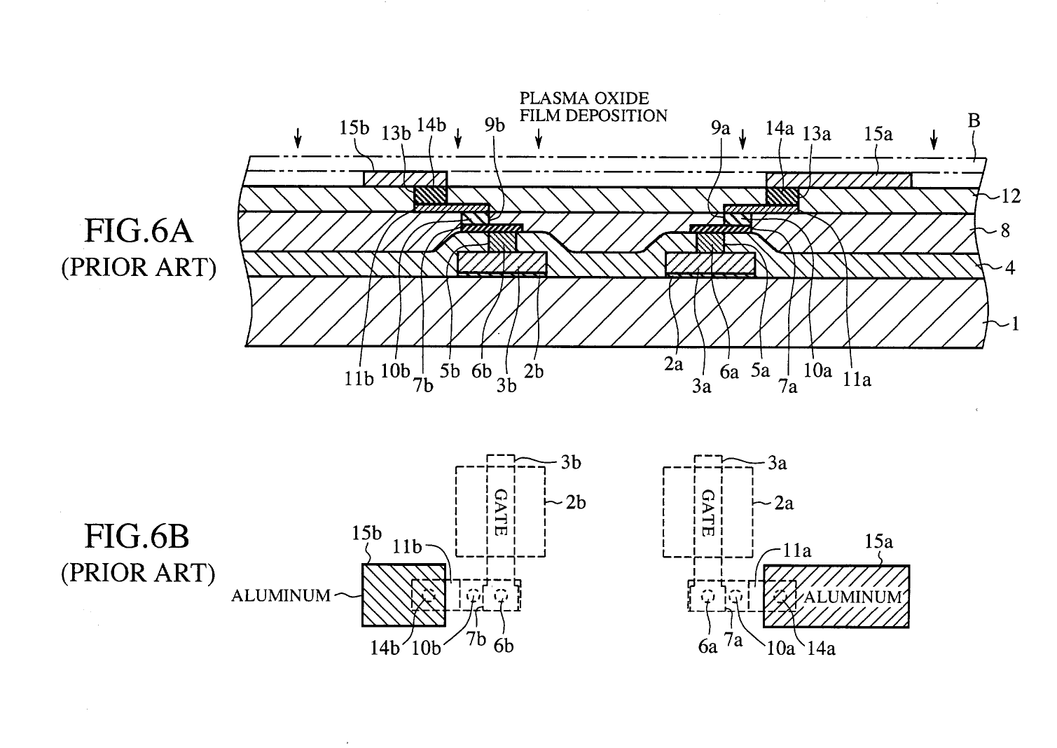

FIG. 4A is a sectional view showing a metallization patterning process in a method of manufacturing a semiconductor device according to the fourth embodiment of the invention. FIG. 4B is a sectional view showing an interlayer formation process over the metal wiring following the metallization patterning process as a post-process shown in FIG. 4A. In the fourth embodiment the same components as the ones in the first embodiment are designated by the same reference numerals, and thus the descriptions thereof are omitted.

The feature of the fourth embodiment is in that the two transistors share the sameness in exposed area to be subjected to the plasma process in first metal wiring layers 6a and 6b, second metal wiring layers 7a and 7b, third metal wiring layers 10a and 10b, fourth metal wiring layers 11a and 11b, fifth metal wiring layers 14a and 14b, and sixth metal wiring layers 15a and 15b, and in that the exposed area is further reduced as small as possible. That is, in the fourth embodiment, each metal wiring layer is formed in a simple and compact shape as shown in FIGS. 4A and 4B.

As mentioned above, according to the fourth embodiment, the following effect is obtained besides that by the first embodiment or the second embodiment. That is, according to the fourth embodiment, since the surface area and the side surface area of each metal wiring layer are reduced as small as possible, the damage induced by plasma that is caused to the gate oxide film of each transistor can also be reduced as small as possible.

As mentioned above, according to the present invention, since a semiconductor device including a plurality of transistors having the same characteristics formed on the same semiconductor substrate is constructed such that the transistors share the sameness in antenna ratio between the area of the gate oxide film of each transistors and the exposed area of a metal wiring to be subjected to the plasma process, electrically connected with a gate electrode formed on the gate oxide film, each transistor suffers from the damage of the same level induced by plasma that is caused to the gate oxide films, and therefore a plurality of transistors can have the same characteristics.

According to the present invention, since the metal wiring is connected with another circuit formed on the same semiconductor substrate, the gate oxide film on the transistor including the metal wiring does not suffer from the damage induced by plasma transmitted from other circuits even through the invention takes such a structure. As a result, since the gate oxide film suffers only from the damage induced by plasma within the transistor, freedom in the design of the metal wiring can be maintained.

According to the present invention, since the transistors share the sameness in exposed area to be subjected to the plasma process, the transistors suffer from the damage of the same level induced by plasma that is caused to the gate oxide films. As a result, each transistor can have the same characteristics.

According to the present invention, since a method of manufacturing a semiconductor device including a plurality of transistors having the same characteristics formed on the same semiconductor substrate is constructed such that the method comprises the step of directly applying plasma process to a metal wiring, electrically connected with a gate electrode formed on the gate oxide film of each transistor, and upon applying the plasma process the transistors share the sameness in antenna ratio between the area of the gate oxide film of each transistor and the exposed area of the metal wiring to be subjected to the plasma process, electrically connected with the gate electrode formed on the gate oxide film, the transistors suffer from the damage of the same level induced by plasma that is caused to the gate oxide films. As a result, a semiconductor device including a plurality of transistors having the same characteristics can be manufactured.

According to the present invention, since the metal wiring is connected with another circuit formed on the same semiconductor substrate before applying the plasma process, the gate oxide film in the transistor including the metal wiring does not suffer from the damage induced by plasma transmitted from other circuits even through the invention takes such a structure. As a result, since the gate oxide film suffers only from the damage induced by plasma within the transistor, freedom in the design of the metal wiring can be maintained.

According to the present invention, since the transistors share the sameness in exposed area to be subjected to the plasma process, the transistors suffer from the damage of the same level induced by plasma that is caused to the gate oxide films, and therefore each transistor can have the same characteristics.

While, in the above prior arts and preferred embodiments of the invention, it should be understood by those skilled in the art that various modifications and changes may be made without departing from the sprit and scope of the invention.

Also, it should be noted that the invention meets all the objects mentioned above and also has the advantages of wide commercial utility, and that the invention has been set forth for purposes of illustration only and not of limitation. That is, the invention is limited only by the following claims which follow. Consequently, reference should be made to the following claims in determining the full scope of the invention.

What is claimed is:

1. A semiconductor device including a plurality of transistors having the same characteristics formed on the same semiconductor substrate, wherein said transistors share the sameness in antenna ratio between an area of a gate oxide film of said transistor and an area of a metal wiring electrically connected with a gate electrode formed on said gate oxide film.

2. The semiconductor device according to claim 1, wherein said metal wiring is connected with another circuit formed on the same semiconductor substrate.

3. The semiconductor device according to claim 1, wherein said transistors share the sameness in exposed area of the metal wiring to be subjected to the plasma process.
